(19) United States
(12) Patent Application Publication
(10) Pub. No.: US 2017/0125533 A1
(43) Pub. Date: May 4, 2017

(54) SEMICONDUCTOR APPARATUS

(71) Applicant: FUJITSU LIMITED, Kawasaki-shi (JP)

(72) Inventors: JUNJI KOTANI, Atsugi (JP); NORIKAZU NAKAMURA, Sagamihara (JP)

(73) Assignee: FUJITSU LIMITED, Kawasaki-shi (JP)

(21) Appl. No.: 15/259,080

(22) Filed: Sep. 8, 2016

(30) Foreign Application Priority Data
Oct. 30, 2015 (JP) 2015-215110

(51) Int. Cl. H01L 29/423; H01L 29/205; H01L 29/417; H01L 29/778; H03F 3/24; H01L 23/495; H02M 3/335; H03F 1/32; H03F 3/189; H01L 29/20; H01L 29/40

(52) U.S. Cl. CPC H01L 29/42316; H01L 29/2003; H01L 29/205; H01L 29/41758; H01L 29/7787; H01L 29/408; H01L 23/49513; H01L 23/4952; H01L 23/49562; H02M 3/33507; H03F 1/3241; H03F 3/189; H03F 3/24; H03F 2201/3206; H03F 2200/333

(57) ABSTRACT

A semiconductor apparatus includes a semiconductor chip including a first semiconductor layer formed over a substrate, a second semiconductor layer formed over the first semiconductor layer, and a gate electrode, a source electrode, and a drain electrode formed over the second semiconductor layer. The gate electrode is formed in a comb shape having a plurality of tooth parts. An interval between the tooth parts becomes narrower from a center part toward a peripheral part of the semiconductor chip. The source electrode is formed on one of two sides of each of the tooth parts in the gate electrode, and the drain electrode is formed on another of the two sides. The source electrodes and the drain electrodes formed between the tooth parts in the gate electrode have respective areas that are substantially the same in a plan view.

### CROSS-REFERENCE TO RELATED APPLICATIONS

This application is based upon and claims the benefit of priority of the prior Japanese Priority Application No. 2015-215110 filed on Oct. 30, 2015, the entire contents of which are hereby incorporated by reference.

### FIELD

The present disclosure relates to a semiconductor apparatus.

### BACKGROUND

Nitride semiconductors have characteristics such as high saturation speed of electrons and wide band gaps, and by taking advantage of these characteristics, have been under investigation to be used as high-voltage tolerance, high-output semiconductor apparatuses. For example, GaN being a nitride semiconductor has the band gap of 3.4 eV, which is greater than the band gap of Si (1.1 eV) and the band gap of GaAs (1.4 eV), and has a high breakdown electric field strength. Therefore, nitride semiconductors such as GaN are extremely promising as materials of semiconductor devices used for power sources to obtain high-voltage operations and high-output.

There have been a considerable number of reports about semiconductor devices using nitride semiconductors, including electric field effect transistors, especially, high electron mobility transistors (HEMT). For example, as a GaN HEMT, a HEMT constituted with AlGaN/GaN has drawn attention, in which GaN is used as an electron transit layer and AlGaN is used as an electron supply layer. In such a HEMT constituted with AlGaN/GaN, distortion is generated in AlGaN due to the difference of the lattice constants between GaN and AlGaN. The distortion generates piezoelectric polarization and spontaneous polarization difference of AlGaN, with which highly concentrated 2DEG (Two-Dimensional Electron Gas) is obtained.

Incidentally, in a high-output semiconductor apparatus, the semiconductor apparatus generates heat during operation because a high current flows at a high voltage. Therefore, as countermeasures for heat generation in such a semiconductor apparatus, there has been development of thin-film substrates to increase heat radiation, and packages having better heat radiation. Also, in a high-output semiconductor apparatus, the gate width is lengthened as much as possible to be operational with a high current. Specifically, the gate electrode is formed in a comb shape having multiple tooth parts, and a source electrode and a drain electrode are formed on respective sides of each of the teeth of the gate electrode. This makes it possible for a semiconductor apparatus formed as a semiconductor chip having a shape of several mm square, to make the effective value of the gate width of the gate electrode greater than or equal to 1 cm, and to lengthen the gate width of the gate electrode in the semiconductor apparatus. Note that in a GaN HEMT, an electron transit layer made of GaN and an electron supply layer made of AlGaN are formed over the substrate, and the gate electrode, the source electrode, and the drain electrode are formed over the electron supply layer made of AlGaN.

In a semiconductor apparatus having the gate electrode formed in a comb shape in this way, in general, the teeth of the gate electrode having a comb shape are formed with uniform intervals, and the gate width of the teeth is uniform. Therefore, the gate electrode, the source electrode, and the drain electrode are formed to have a periodic pattern of placement of the electrodes. Therefore, the pattern of placement of the electrodes of the gate electrode, the source electrode, and the drain electrode is the same at a center part and at a peripheral part of the semiconductor chip.

### RELATED-ART DOCUMENTS

### Patent Documents

### [Patent Document 1] Japanese Unexamined Patent Application Publication No. 2005-509295

### [Patent Document 2] Japanese Laid-open Patent Publication No. 7-283235

### [Patent Document 3] Japanese Laid-open Patent Publication No. 11-87367

However, there may be a case where sufficient output is not obtained just by forming the gate electrode in a comb shape. Therefore, it has been desired to develop a semiconductor apparatus having the gate electrode formed in a comb shape with which higher output is obtained.

### SUMMARY

According to an embodiment, a semiconductor apparatus includes a semiconductor chip including a first semiconductor layer formed over a substrate, a second semiconductor layer formed over the first semiconductor layer, and a gate electrode, a source electrode, and a drain electrode formed over the second semiconductor layer. The gate electrode is formed in a comb shape having a plurality of tooth parts. An interval between the tooth parts becomes narrower from a center part toward a peripheral part of the semiconductor chip. The source electrode is formed on one of two sides of each of the tooth parts in the gate electrode, and the drain electrode is formed on another of the two sides. The source electrodes and the drain electrodes formed between the tooth parts in the gate electrode have respective areas that are substantially the same in a plan view.

The object and advantages of the embodiment will be realized and attained by means of the elements and combinations particularly pointed out in the claims. It is to be understood that both the foregoing general description and the following detailed description are exemplary and explanatory and are not restrictive of the invention as claimed.

### BRIEF DESCRIPTION OF DRAWINGS

FIGS. 1A-1B is first diagrams illustrating a semiconductor apparatus having a comb-shaped gate electrode;

FIG. 2 is a second diagram illustrating a semiconductor apparatus having a comb-shaped gate electrode;

FIG. 3 is a top view of a semiconductor chip having a semiconductor apparatus formed according to a first embodiment;

FIG. 4 is a correlation diagram of difference between cut-off frequencies ft of two transistors and composite output;

FIG. 5 is a diagram illustrating a relationship between the area S of an electrode and the cut-off frequency ft;

FIG. 6 is a diagram illustrating the area of an electrode of a semiconductor apparatus according to the first embodiment;

FIG. 7 is a distribution diagram of temperature of a semiconductor chip having a semiconductor apparatus formed;

FIG. 8 is a structural diagram illustrating a semiconductor apparatus according to the first embodiment;

FIG. 9 is a top view of a semiconductor chip having a semiconductor apparatus formed according to a second embodiment;

FIG. 10 is a first diagram illustrating a semiconductor apparatus according to the second embodiment;

FIG. 11 is a correlation diagram of the electrode width Wp of a partitioned part and the contact resistance of the electrode;

FIG. 12 is a diagram illustrating the electrode width Wp of a partitioned part;

FIG. 13 is a second diagram illustrating a semiconductor apparatus according to the second embodiment;

FIG. 14 is a diagram illustrating a semiconductor apparatus installed in a discrete package according to a third embodiment;

FIG. 15 is a circuit diagram of a power supply apparatus according to the third embodiment; and

FIG. 16 is a structural diagram of a high-frequency amplifier according to the third embodiment.

### DESCRIPTION OF EMBODIMENTS

In the following, embodiments will be described with reference to the drawings. Note that the same numerical codes are assigned to the same members, and their description may be omitted.

According to an embodiment, higher output can be obtained for a semiconductor apparatus having the gate electrode formed in a comb shape.

Incidentally, in a semiconductor apparatus having the gate electrode formed in a comb shape, if the placement pattern of the electrodes is the same for the center part and the peripheral part of the semiconductor chip, heat is radiated to the outside of the semiconductor chip from the peripheral part, but radiated less easily from the center part. Therefore, the center part of the semiconductor chip tends to accumulate the heat, and tends to have a higher temperature.

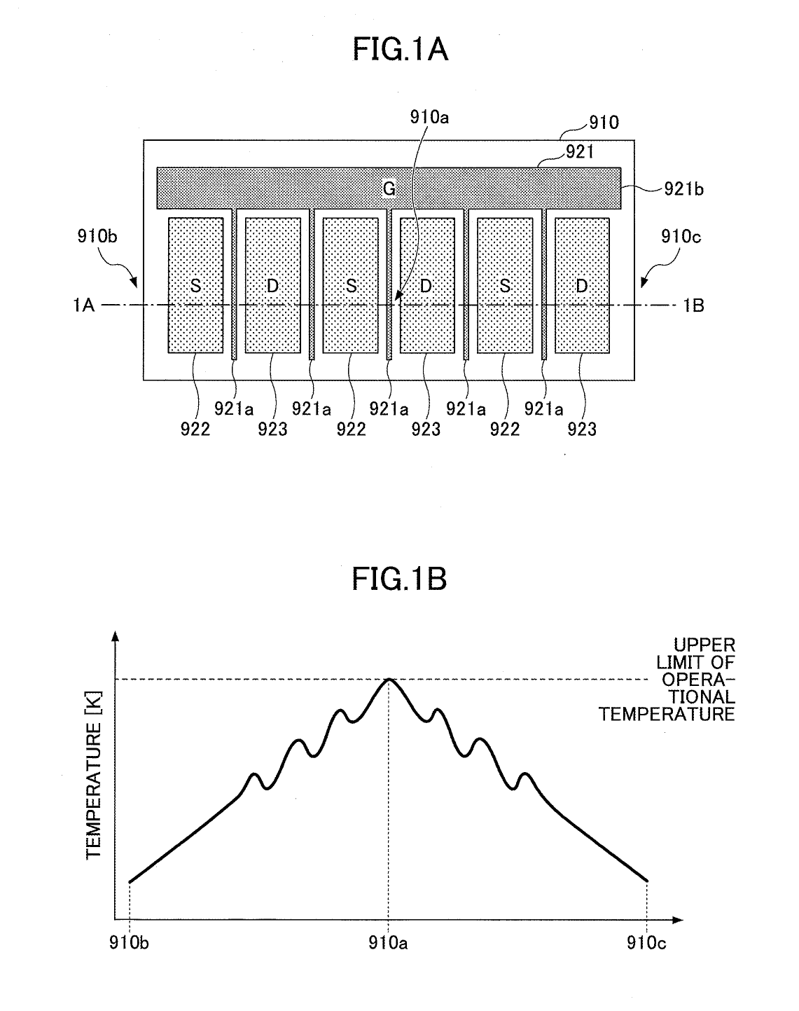

Specifically, a semiconductor apparatus having the gate electrode formed in a comb shape may have, as illustrated in FIG. 1A, a comb-shaped gate electrode 921 formed over a surface of a semiconductor chip 910, and tooth parts 921a of the comb-shaped gate electrode 921 are formed at uniform intervals. The gate electrode 921 has each of the tooth parts 921a connected with a connecting part 921b, and source electrodes 922 and drain electrode 923 are formed on respective sides of the tooth parts 921a of gate electrode 921. Therefore, between a tooth part 921a and another tooth part 921a adjacent to each other, a source electrode 922 or a drain electrode 923 is disposed alternately. Consequently, a source electrode 922, a tooth part 921a of the gate electrode 921, a drain electrode 923, and another tooth part 921a of the gate electrode 921 are cyclically formed in this order in the longitudinal direction of the semiconductor chip 910. Accordingly, an on current flowing in the center part of the semiconductor chip 910 is substantially the same as an on current flowing in the peripheral part, and generated heat is also substantially the same.

FIG. 1B illustrates distribution of temperature of a part of the semiconductor chip 910 cut along a dashed-dotted line 1A-1B in FIG. 1A when the semiconductor apparatus illustrated in FIG. 1A is operated. As illustrated in FIG. 1B, the semiconductor chip 910 has the highest temperature at the center part 910a, and lower temperatures toward peripheral parts 910b and 910c. The peripheral parts 910b and 910c of the semiconductor chip 910 have comparatively low temperatures because generated heat is more easily radiated to the outside, whereas the center part 910a has a higher temperature because the generated heat is less easily radiated and tends to be accumulated.

Incidentally, although it is desirable for a semiconductor apparatus used for high-output applications to be operational with high output, high-output operation may raise the temperature by heat generation, and may break down the semiconductor apparatus. Therefore, the upper limit of the operational temperature is defined for a semiconductor apparatus, and the semiconductor apparatus is operated at a temperature not exceeding the upper limit of the operational temperature to prevent the semiconductor apparatus from being broken down. Accordingly, the semiconductor apparatus having the structure illustrated in FIG. 1A, which has the highest temperature at the center part 910a of the semiconductor chip 910, is operated to generate output so that the temperature at the center part 910a does not exceed the upper limit of the operational temperature.

Here, if the semiconductor chip 910 is operated so that the temperature at the center part 910a does not exceed the upper limit of the operational temperature as illustrated in FIG. 1B, the temperature at the peripheral parts 910b and 910c of the semiconductor chip 910 has a fairly substantial margin with respect to the upper limit of the operational temperature.

Therefore, it is still possible to flow a higher current in the peripheral parts 910b and 910c of the semiconductor chip 910, and if such a higher current can actually flow in the peripheral parts 910b and 910c of the semiconductor chip 910, the output of the semiconductor apparatus can be made higher. In other words, if the temperature of the semiconductor chip 910 can be controlled to be uniform across the chip while the semiconductor apparatus is operated, a current can flow to an extent until the temperature of the semiconductor chip 910 as a whole gets close to the upper limit of the operational temperature, and the output of the semiconductor apparatus can be made higher.

Here, as a method for making the temperature of the semiconductor chip 910 as a whole be nearly uniform, a method may be considered that makes the gate width of the tooth parts 921a of the gate electrode 921 at the center part of the semiconductor chip 910, shorter than the gate width of the tooth parts 921a of the gate electrode 921 at the peripheral parts. In this case, an on current flowing in the center part of the semiconductor chip 910 is lower than an on current flowing in the peripheral parts, and hence, the temperature rise can be checked at the center part of the semiconductor chip 910. Thus, the temperature at the center part of the semiconductor chip 910 and the temperature at the peripheral parts can be made nearly uniform. However, the gate width of the tooth parts 921a of the gate electrode 921 at the center part is shorter, and accordingly, the output becomes lower, and the output of the entire apparatus becomes lower.

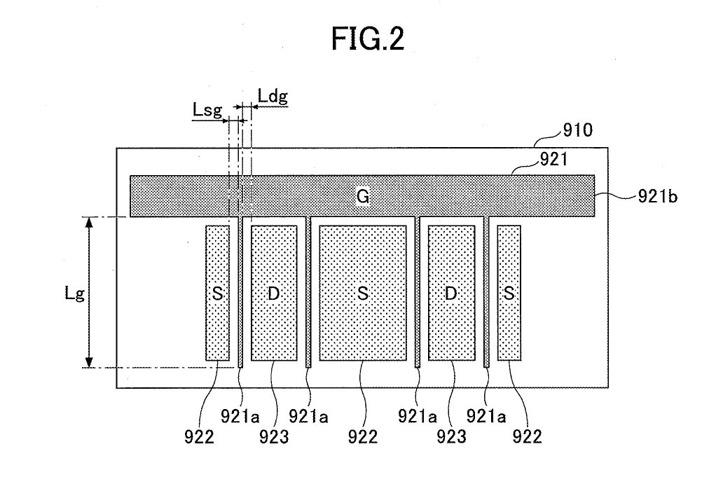

Therefore, as another method for making the temperature of the semiconductor chip 910 as a whole be nearly uniform, as illustrated in FIG. 2, a method may be considered that makes the gate width Lg of the tooth parts 921a uniform, but makes the interval of the tooth parts 921a of the gate electrode 921 wider at the center part, and narrower at the peripheral parts. In this case, the source-gate interval Lsg between a tooth part 921a of the gate electrode 921 and a source electrode 922 is required to be uniform, and the drain-gate interval Ldg between a tooth part 921a of the gate electrode 921 and a drain electrode 923 is required to be uniform. Therefore, the area of the source electrode 922 and the drain electrode 923 is greater at the center part of the semiconductor chip 910 and smaller at the peripheral parts. Therefore, the parasitic capacitance of the electrode in a transistor becomes different between the center part and the peripheral parts of the semiconductor chip 910. If the parasitic capacitance of the electrode in a transistor is different at the center part of the semiconductor chip 910 compared to the peripheral parts of the semiconductor chip 910, voltage/current phases are not synchronized in the semiconductor chip 910, and the efficiency is reduced considerably.

### First Embodiment

(Semiconductor Apparatus)

Next, a semiconductor apparatus will be described according to a first embodiment. The semiconductor apparatus according to the embodiment has nitride semiconductor films including a nucleation layer, a buffer layer, an electron transit layer, and an electron supply layer, formed over a substrate, and has a gate electrode, a source electrode, and a drain electrode formed over the electron supply layer. According to the embodiment, a dicing process is applied to the substrate after having these layers formed, to be separated into individual semiconductor apparatuses, each of which will be referred to as a “semiconductor chip 10”. Note that the structure of the semiconductor layers in the semiconductor apparatus will be described later.

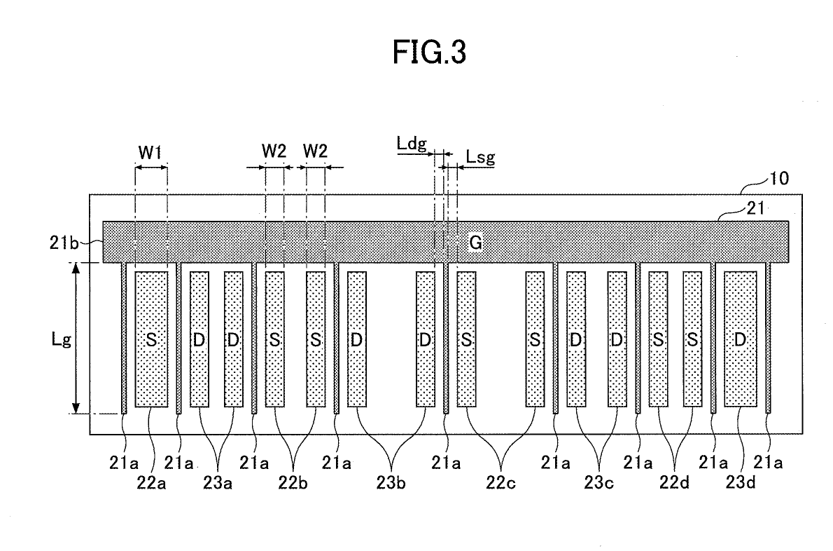

As illustrated in FIG. 3, the semiconductor apparatus according to the embodiment has a comb-shaped gate electrode 21 formed over a surface of the semiconductor chip 10, and the gate width Lg is uniform for the tooth parts 21a in the gate electrode 21. The interval of the tooth parts 21a in the comb-shaped gate electrode 21 is the widest at the center part of the semiconductor chip 10, becomes gradually narrower toward the peripheral parts, and is the narrowest at the end of the peripheral parts. The gate electrode 21 has each of the tooth parts 21a connected with a connecting part 21b, and source electrodes and drain electrodes are formed on respective sides of the tooth parts 21a of gate electrode 21. In other words, a source electrode is formed on one side among two sides of a tooth part 21a in the gate electrode 21, and a drain electrode is formed on the other side. Therefore, between a tooth part 21a and another tooth part 21a adjacent to each other, a source electrode or a drain electrode is disposed alternately.

Specifically, several tooth parts 21a of the gate electrode 21 are formed so that the interval of the tooth parts 21a becomes gradually wider toward the center part from the peripheral part on the left side of the semiconductor chip 10 in FIG. 3. A source electrode 22a, drain electrodes 23a, source electrodes 22b, and drain electrodes 23b are formed in this order between the tooth parts 21a adjacent to each other in the gate electrode 21, from the peripheral part on the left side of the semiconductor chip 10 toward the center part.

Also, the other tooth parts 21a of the gate electrode 21 are formed so that the interval of the tooth parts 21a becomes gradually narrower toward the peripheral part on the right side of the semiconductor chip 10 in FIG. 3 from the center part. Source electrodes 22c, drain electrodes 23c, source electrodes 22d, and a drain electrode 23d are formed in this order between the tooth parts 21a adjacent to each other in the gate electrode 21, from the center part toward the peripheral part on the right side of the semiconductor chip 10. Note that the source-gate interval Lsg is uniform between a tooth part 21a and a source electrode 22 of the gate electrode 21, and the drain-gate interval Ldg is uniform between a tooth part 21a and a drain electrode 23 of the gate electrode 21.

According to the embodiment, as illustrated in FIG. 3, the source electrode 22a and the drain electrode 23d are single electrodes, respectively, whereas the source electrodes 22b, 22c and 22d, and the drain electrodes 23a, 23b, and 23c are bi-partitioned, respectively. Note that the source electrodes 22b, the source electrodes 22c, and the source electrodes 22d have respective partitioned parts electrically connected with each other by bonding wires or the like. Also, the drain electrodes 23a, the drain electrodes 23b, and the drain electrodes 23c have respective partitioned parts electrically connected with each other by bonding wires or the like.

According to the embodiment, to make the parasitic capacitance uniform as much as possible, the electrodes are formed so that the areas of the source electrodes are substantially the same, and the areas of the drain electrodes are substantially the same. Therefore, the source electrodes 22 are formed so that the area of the source electrode 22a, the area of the source electrodes 22b, the area of the source electrodes 22c, and the area of the source electrodes 22d are substantially the same. Also, the drain electrodes 23 are formed so that the area of the drain electrodes 23a, the area of the drain electrodes 23b, the area of the drain electrodes 23c, and the area of the drain electrode 23d are substantially the same.

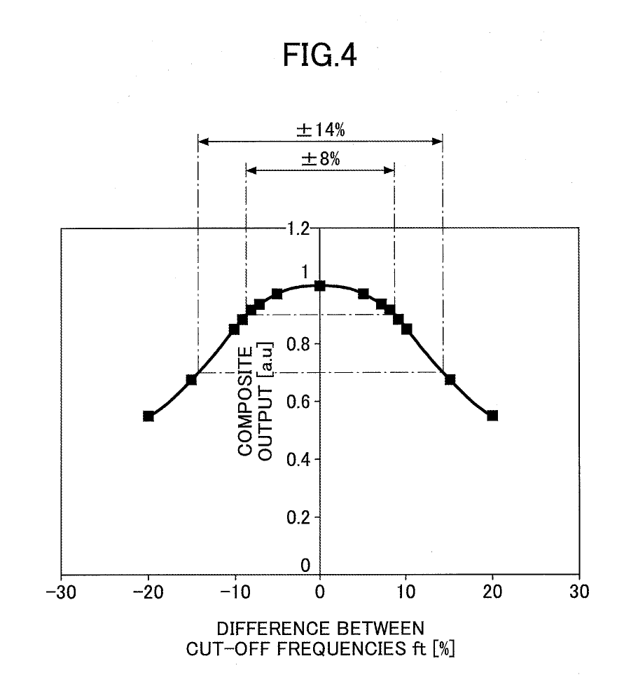

If the width of the source electrodes and the drain electrodes becomes wider in the longitudinal direction of the semiconductor chip 10, the area of the source electrodes and the drain electrodes becomes greater. Consequently, the parasitic capacitance increases, and the cut-off frequency ft is lowered, which is an indicator of the high frequency characteristic in the semiconductor apparatus. FIG. 4 illustrates a relationship of difference between the cut-off frequencies ft of two transistors, and composite output obtained by composition of the two transistors. As illustrated in FIG. 4, the composite output takes the maximum when the difference between the cut-off frequencies ft of the two transistors is zero, and decreases while the difference between the cut-off frequencies ft of the two transistors becomes greater. Representing the value of the composite output as 1 when the difference between the cut-off frequencies ft of the two transistors is zero, if the difference between the cut-off frequencies ft of the two transistors is less than or equal to 8%, composite output of 0.9 (90%) or greater can be obtained. Also, if the difference between the cut-off frequencies ft of the two transistors is less than or equal to 14%, composite output of 0.7 (70%) or greater can be obtained.

If the composite output decreases, increased loss of electric power due to the decreased amount of output increases the heat quantity generated in the semiconductor chip 10. Consequently, the temperature rises in the semiconductor chip 10, and the mobility of electrons drops. Such drop of the mobility of electrons leads to drop of the operational efficiency of a transistor. In other words, a negative feedback loop of the drop of the operational efficiency of the transistor, and the drop of the mobility of electrons makes the output characteristic of the transistor get worse steadily. Therefore, for a semiconductor apparatus having the gate electrode formed in a comb shape, it is extremely important for practical use to keep the characteristic of the transistors uniform, and to make output composition efficient.

Based on knowledge of the inventors, for composite output of transistors having the same characteristic, if the composite output drops to be less than 90%, drop of the output and heat generation described above are started, and if the composite output further drops to be less than 70%, the drop of the output and the heat generation become notable. Therefore, it is preferable that the composite output of transistors is greater than or equal to 70% with respect to the composite output of the transistors having the same characteristic, and further preferable to be greater than or equal to 90%.

Note that the transistor described above is a transistor formed by a tooth part 21a of the gate electrode 21 and a source electrode and a drain electrode on respective sides in the semiconductor chip 10 in FIG. 3. Therefore, the two transistors described above may consist of a transistor having the gate electrode of the tooth part 21a at the center part of the semiconductor chip 10 in FIG. 3, and a transistor having the gate electrode of a tooth part 21a at a peripheral part of the semiconductor chip 10. For example, one of the transistors is formed by the tooth part 21a of the center part of the semiconductor chip 10, the source electrode 22c, and the drain electrode 23b, and the other transistor is formed by the tooth part 21a at peripheral part of the semiconductor chip 10, the source electrode 22a, and the drain electrode 23a.

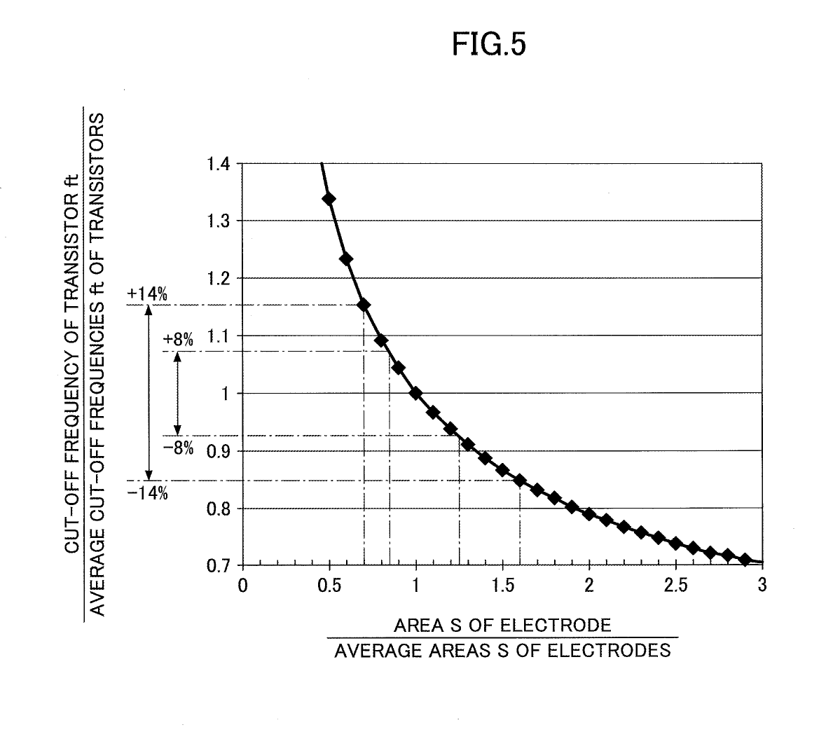

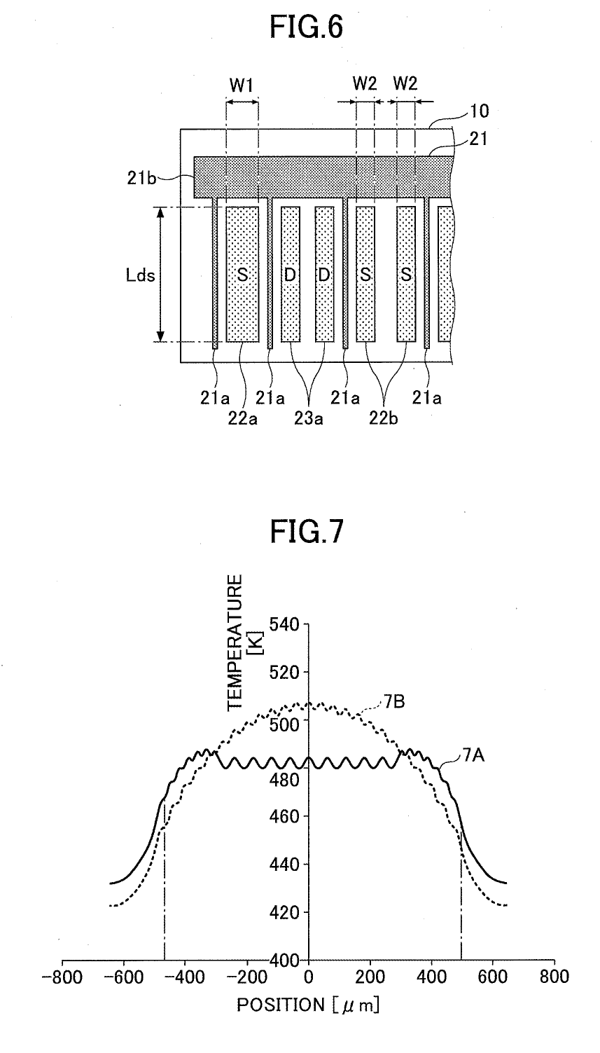

As described above, if the width of the source electrodes and the drain electrodes becomes wider in the longitudinal direction of the semiconductor chip 10, the area of the source electrodes and the drain electrodes becomes greater, and accordingly, the parasitic capacitance increases, and the cut-off frequency ft is lowered. FIG. 5 illustrates a relationship between the area S of each source electrode and drain electrode, relative to the average of the areas S of the electrodes in the semiconductor chip 10, and the cut-off frequency ft of each transistor, relative to the average of the cut-off frequencies ft of the transistors in the semiconductor chip 10. Note that the area S of an electrode in a source electrode or a drain electrode is calculated, as illustrated in FIG. 6, for the source electrode 22a or the like being a single electrode, for example, by a product of the length Lds of the source electrode 22a and the width W1, namely, S=Lds×W1. Also, for the bi-partitioned source electrodes 22b, S is calculated by S=2×Lds×W2 where W2 is the width of a partitioned region of the source electrodes 22b.

From FIG. 5, values of the cut-off frequencies ft of the transistors relative to the average of the cut-off frequencies ft of the transistors that are greater than or equal to 0.86 and less than or equal to 1.14, correspond to values of the areas S of the electrodes relative to the average of the areas S of the electrodes that are greater than or equal to 0.7 and less than or equal to 1.6. In other words, a range in which differences between the average of the cut-off frequencies ft of the transistors, and values of the cut-off frequencies ft of the transistor, fall within 14% relative to the average of the cut-off frequencies ft of the transistors, corresponds to values of the areas S of the electrodes relative to the average of the areas S of the electrodes that are greater than or equal to 0.7 and less than or equal to 1.6. Therefore, it is preferable that values of the areas S of the electrodes relative to the average of the areas S of the electrodes are greater than or equal to 0.7 and less than or equal to 1.6.

Also, values of the cut-off frequencies ft of the transistors relative to the average of the cut-off frequencies ft of the transistors that are greater than or equal to 0.92 and less than or equal to 1.08, correspond to values of the areas S of the electrodes relative to the average of the areas S of the electrodes that are greater than or equal to 0.85 and less than or equal to 1.25. In other words, a range in which differences between the average of the cut-off frequencies ft of the transistors, and values of the cut-off frequencies ft of the transistor, fall within 8% relative to the average of the cut-off frequencies ft of the transistors, corresponds to values of the areas S of the electrodes relative to the average of the areas S of the electrodes that are greater than or equal to 0.85 and less than or equal to 1.25. Therefore, it is further preferable that values of the areas S of the electrodes relative to the average of the areas S of the electrodes are greater than or equal to 0.85 and less than or equal to 1.25.

As described above, in the semiconductor apparatus according to the embodiment, by making the areas S of the electrodes in the source electrodes and the drain electrodes nearly uniform, distribution of the temperature can be made uniform as illustrated in FIG. 7. FIG. 7 is a result of heat simulation for a semiconductor apparatus. A curve 7A represents a temperature distribution characteristic of the semiconductor apparatus according to the embodiment illustrated in FIG. 3, and a curve 7B represents a temperature distribution characteristic of the semiconductor apparatus illustrated in FIG. 1. Note that in this heat simulation, the number of tooth parts in the gate electrode is set to 25. The number of the tooth parts in a gate electrode corresponds to the number of transistors, and the transistors are formed within a range between −500 μm and +500 μm in the semiconductor chip. Also, the output of the semiconductor chip is the same for the semiconductor apparatus according to the embodiment illustrated in FIG. 3, and for the semiconductor apparatus illustrated in FIG. 1.

As designated by the curve 7B, the distribution of the temperature of the semiconductor apparatus illustrated in FIG. 1 has a peak of the temperature about 505 K at the center part of the semiconductor chip, and the temperature difference between the center part and the peripheral parts of the semiconductor chip is greater than or equal to 60 K. On the other hand, as designated by the curve 7A, the distribution of the temperature of the semiconductor apparatus according to the embodiment illustrated in FIG. 3 exhibits the temperature difference less than or equal to 20 K between the center part and the peripheral parts of the semiconductor chip. Also, the maximum value of the temperature of the semiconductor chip designated by the curve 7A is about 485 K, which is lower than that designated by the curve 7B by about 20 K. Note that the semiconductor apparatus according to the embodiment can be further optimized to make the temperature difference between the center part and the peripheral parts of the semiconductor chip less than or equal to 10 K.

Thus, compared to the semiconductor apparatus illustrated in FIG. 1, the semiconductor apparatus according to the embodiment can make the distribution of the temperature uniform, and the maximum temperature lower. Therefore, the semiconductor apparatus according to the embodiment can realize higher output.

(Structure of Semiconductor Apparatus)

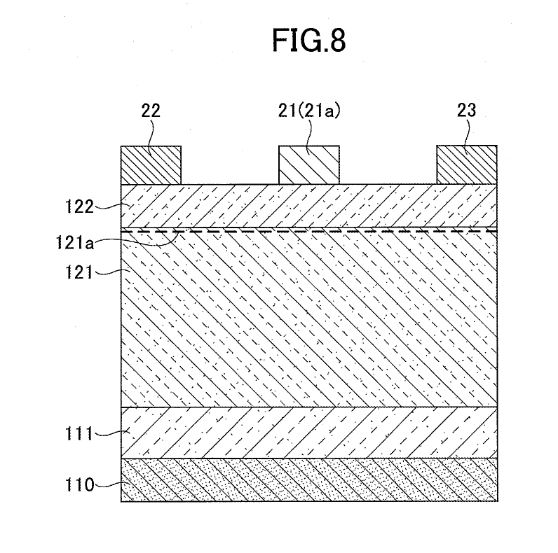

Next, the structure of the semiconductor layers in the semiconductor apparatus will be described according to the embodiment. The semiconductor apparatus according to the embodiment uses a nitride semiconductor having a wide band gap as a semiconductor material for high output. Specifically, as illustrated in FIG. 8, a nucleation layer (not illustrated), a buffer layer 111, an electron transit layer 121, and an electron supply layer 122 are formed over a substrate 110 such as a silicon (Si) substrate and the like. A gate electrode 21, a source electrode 22, and a drain electrode 23 are formed over the electron supply layer 122. Although the source electrode 22 and the drain electrode 23 are actually bi-partitioned, one of the partitions is drawn in FIG. 8 for convenience's sake. Also, the gate electrode 21 illustrated in FIG. 8 is a tooth part 21a of the comb-shaped gate electrode 21. In the present application, the electron transit layer 121 may be referred to as a first semiconductor layer, and the electron supply layer 122 may be referred to as a second semiconductor layer.

Nitride semiconductor films including the nucleation layer (not illustrated), the buffer layer 111, the electron transit layer 121, and the electron supply layer 122 formed over the substrate 110 are formed by epitaxial growth. The epitaxial growth of the nitride semiconductor films may be executed by MOCVD (Metal Organic Chemical Vapor Deposition) or MBE (Molecular Beam Epitaxy). In the embodiment, a case will be described where the nitride semiconductor film are formed by epitaxial growth using MOCVD.

As the substrate 110, a substrate of SiC, sapphire, GaN, or the like may be used other than a silicon substrate. The nucleation layer is formed of an AlN film having the film thickness of about 160 nm, and the buffer layer 111 is formed of an AlGaN film having the film thickness of about 500 nm. The electron transit layer 121 is formed of a GaN film having the film thickness of about 1.3 μm, and the electron supply layer 122 is formed of a Al_{0.2}Ga_{0.8}N film having the film thickness of about 20 μm. This structure generates 2DEG 12 in the electron transit layer 121 in the neighborhood of the interface between the electron transit layer 121 and the electron supply layer 122. The gate electrode 21, the source electrode 22, and the drain electrode 23 are formed over the electron supply layer 122. Note that the electron supply layer 122 may be formed of AlGaN having a composition ratio different from Al_{0.2}Ga_{0.8}N, or InAlN, InAlGaN, or the like. Also, a spacer layer made of a nitride semiconductor may be formed between the electron transit layer 121 and the electron supply layer 122, and a cap layer made of a nitride semiconductor may be formed over the electron supply layer 122, and over the cap layer, the gate electrode 21, the source electrode 22, and the drain electrode 23 may be formed. Furthermore, a passivation film covering the nitride semiconductor films may be formed of an insulator material or the like.

When forming AlN, GaN, AlGaN, and the like by MOCVD, TMA (trimethyl aluminum) is used as a raw material gas of Al, TMG (trimethyl gallium) is used as a raw material gas of Ga, and NH3 (ammonia) is used as a raw material gas of N. These raw material gases are adjusted to be supplied or not, and for the amount of supply so that the films of AlN, GaN, AlGaN, and the like can be formed by epitaxial growth using MOCVD. When forming these nitride semiconductor films by MOCVD, a chamber of a MOCVD apparatus is set to satisfy conditions of the pressure around 50 Torr to 300 Torr, and the temperature around 1000° C. to 1200° C. Also, when forming the electron supply layer 122 of InAlN and InAlGaN, the chamber of the MOCVD apparatus is set to satisfy conditions of the pressure around 50 Torr to 200 Torr, and the temperature around 650° C. to 800° C.

### Second Embodiment

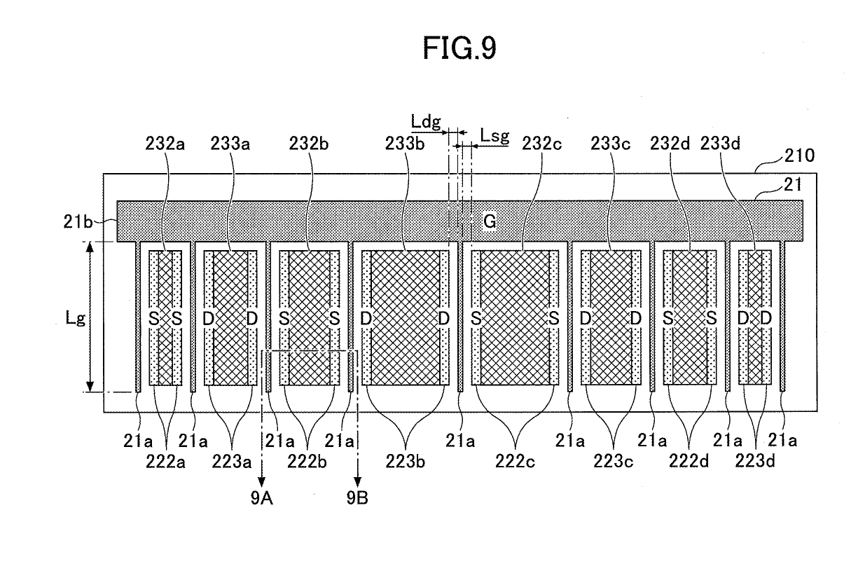

Next, a second embodiment will be described. As illustrated in FIG. 9, a semiconductor apparatus according to the embodiment has a structure in which all source electrodes and drain electrodes are partitioned, and high-heat-conduction parts are formed between respective partitioned source electrodes and drain electrodes.

As illustrated in FIG. 9, the semiconductor apparatus according to the embodiment has a comb-shaped gate electrode 21 formed over a surface of the semiconductor chip 210, and the gate width Lg is uniform for the tooth parts 21a in the gate electrode 21. The interval of the tooth parts 21a in the comb-shaped gate electrode 21 is the widest at the center part of the semiconductor chip 210, gradually narrower toward the peripheral parts, and the narrowest at the end of the peripheral parts. The gate electrode 21 has each of the tooth parts 21a connected with a connecting part 21b, and source electrodes and drain electrodes are formed on respective sides of the tooth parts 21a of gate electrode 21. Therefore, between a tooth part 21a and another tooth part 21a adjacent to each other, a source electrode or a drain electrode is disposed alternately.

Specifically, several tooth parts 21a of the gate electrode 21 are formed so that the interval of the tooth parts 21a becomes gradually wider toward the center part from the peripheral part on the left side of the semiconductor chip 10 in FIG. 9. Source electrodes 222a, drain electrodes 223a, source electrodes 222b, and drain electrodes 223b are formed in this order between the tooth parts 21a adjacent to each other in the gate electrode 21, from the peripheral part on the left side of the semiconductor chip 10 toward the center part.

Also, the other tooth parts 21a of the gate electrode 21 are formed so that the interval of the tooth parts 21a becomes gradually narrower toward the peripheral part on the right side of the semiconductor chip 210 in FIG. 9 from the center part. Source electrodes 222c, drain electrodes 223c, source electrodes 222d, and drain electrodes 223d are formed in this order between the tooth parts 21a adjacent to each other in the gate electrode 21, from the center part toward the peripheral part on the right side of the semiconductor chip 210. Note that the source-gate interval Lsg is uniform between a tooth part 21a and a source electrode 22 of the gate electrode 21, and the drain-gate interval Ldg is uniform between a tooth part 21a and a drain electrode 23 of the gate electrode 21.

According to the embodiment, as illustrated in FIG. 9, the source electrodes 222a, 222b, 222c, and 222d, and the drain electrodes 223a, 223b, 223c, and 223d are bi-partitioned, respectively. Between the respective source electrodes and drain electrodes bi-partitioned in this way, high-heat-conduction parts are formed. Specifically, a high-heat-conduction part 232a is formed between bi-partitioned parts of the source electrodes 222a, and a high-heat-conduction part 233a is formed between bi-partitioned parts of the drain electrodes 223a. A high-heat-conduction part 232b is formed between bi-partitioned parts of the source electrodes 222b, and a high-heat-conduction part 233b is formed between bi-partitioned parts of the drain electrodes 223b. A high-heat-conduction part 232c is formed between bi-partitioned parts of the source electrodes 222c, and a high-heat-conduction part 233c is formed between bi-partitioned parts of the drain electrodes 223c. A high-heat-conduction part 232d is formed between bi-partitioned parts of the source electrodes 222d, and a high-heat-conduction part 233d is formed between bi-partitioned parts of the drain electrodes 223d.

Note that the partitioned parts in each pair of the source electrodes 222a, 222b, 222c, and 222d are electrically connected with each other by a bonding wire or the like. Also, the partitioned parts in each pair of the drain electrodes 223a, 223b, 223c, and 223d are electrically connected with each other by a bonding wire or the like.

The high-heat-conduction parts 232a, 232b, 232c, 232d, 233a, 233b, 233c, and 233d are formed of a material having a high thermal conductivity and an insulation property, such as diamond and monocrystal SiC having an insulation property. Note that it is preferable that the high-heat-conduction parts are formed of a material having a higher thermal conductivity than metal that forms the source electrodes and the drain electrodes.

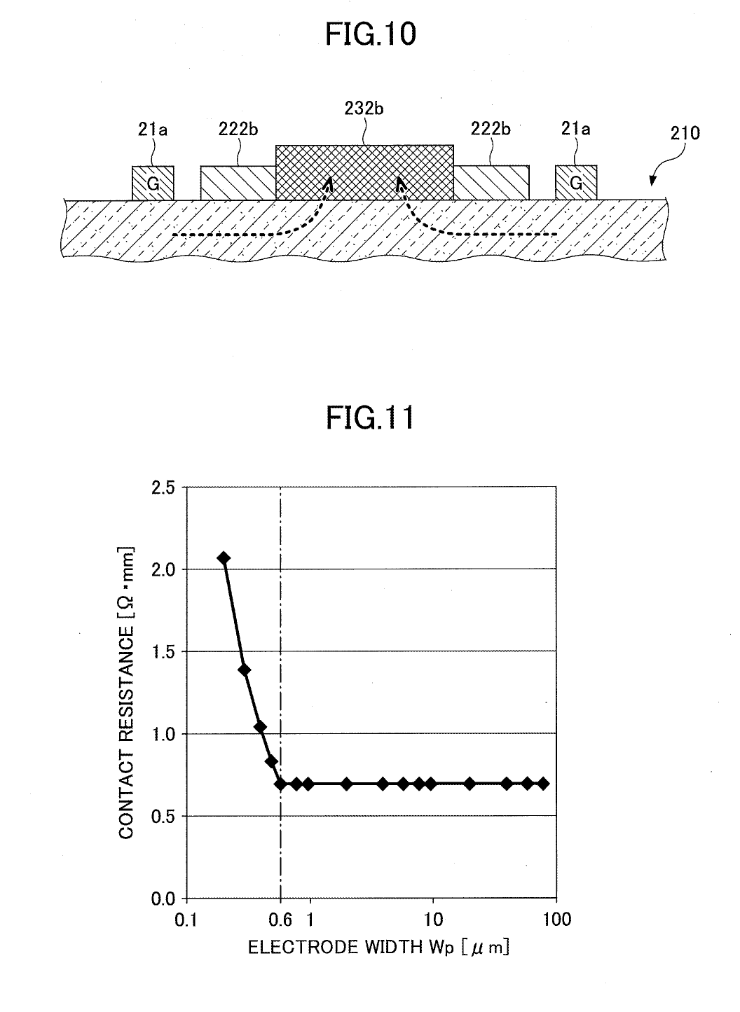

The semiconductor apparatus according to the embodiment can efficiency radiate heat generated in the semiconductor chip 210 by having the high-heat-conduction parts formed between the partitioned parts in the source electrodes and the drain electrodes. Specifically, as illustrated in FIG. 10 by dashed line arrows, heat generated in the semiconductor chip 210 flows toward the high-heat-conduction part 232b formed between the partitioned parts in the source electrode 222b, to be radiated. Since the high-heat-conduction part has a higher thermal conductivity than the metal material forming the source electrodes and the drain electrodes, temperature rise can be checked in the semiconductor chip 210. Note that FIG. 10 is a partial cross sectional view of the semiconductor chip 210 cut off along a dashed-dotted line 9A-9B in FIG. 9.

Incidentally, in the semiconductor apparatus according to the embodiment, the heat radiation effect becomes higher while the area of the high-heat-conduction parts becomes greater. In this case, the width of the partitioned and formed source electrodes and drain electrodes becomes narrower. If the width is too narrow, contact resistance of the electrodes, namely, contact resistance between a nitride semiconductor film and the electrode rises.

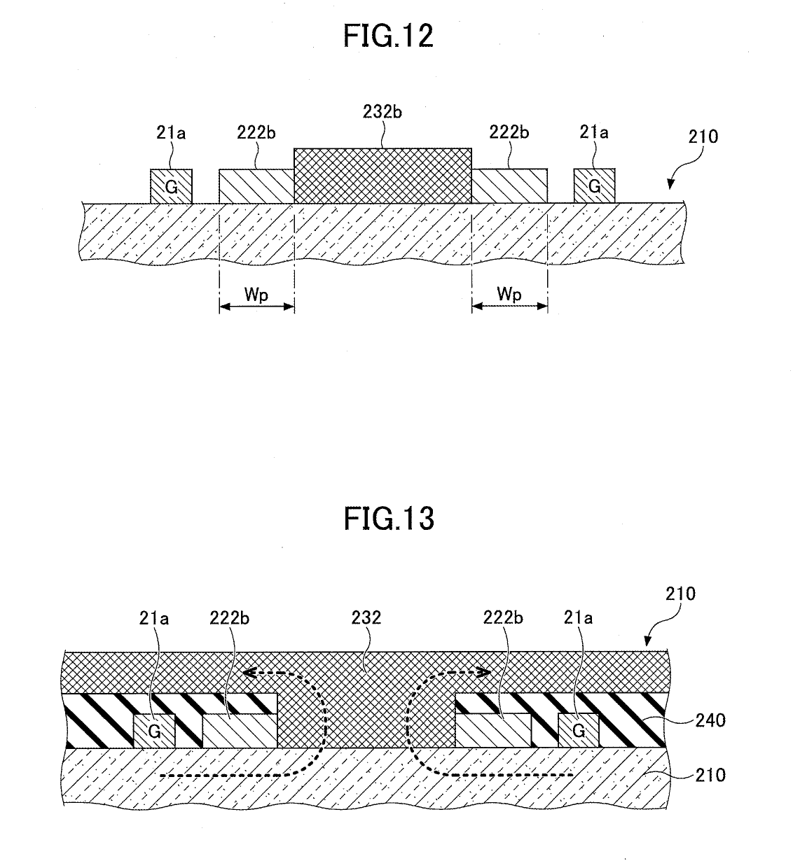

FIG. 11 illustrates a relationship between the electrode width Wp of a bi-partitioned part in the source electrodes and the drain electrodes, and the contact resistance of the electrode. As illustrated in FIG. 12, the electrode width Wp of a partitioned part in the source electrodes and the drain electrodes corresponds to the width of a part on the left side among the bi-partitioned parts in the source electrodes 222b, and also the width of a part on the right side. Note that FIG. 12 is a partial cross sectional view of the semiconductor chip 210 cut off along a dashed-dotted line 9A-9B in FIG. 9.

As illustrated in FIG. 11, if the electrode width Wp of a bi-partitioned part in the source electrodes and the drain electrodes is less than 0.6 μm, the contact resistance of the electrode increases steeply while the electrode width Wp becomes narrower. On the other hand, if the electrode width Wp is greater than or equal to 0.6 μm, the contact resistance of the electrode is virtually constant about 0.7 Ω·cm, and the contact resistance of the electrode remains unchanged while the electrode width Wp becomes wider. Therefore, if the electrode width Wp of a bi-partitioned part in the source electrodes and the drain electrodes is greater than or equal to 0.6 μm, the electrode width Wp does not have an influence on the characteristic of the semiconductor apparatus. Accordingly, if the source electrodes and the drain electrodes are to be bi-partitioned, it is preferable that the electrode width Wp of a partitioned part is greater than or equal to 0.6 μm. Note that it is preferable that the electrode width Wp of a partitioned part is less than or equal to 100 μm because if the electrode width Wp of the partitioned parts is too wide, the semiconductor apparatus becomes larger.

Also, as illustrated in FIG. 13, a passivation film 240 may be formed over each region that includes the gate electrode 21a and a source electrode 222b, to form a high-heat-conduction part 232 on these passivation films 240. Thus, as designated by dashed line arrows, heat generated in the semiconductor chip 210 flows toward the high-heat-conduction part 232 spread over the passivation films 240, and hence, the heat radiation effect can be raised further.

Note that contents other than the above are the same as in the first embodiment.

### Third Embodiment

Next, a third embodiment will be described. The embodiment relates to a semiconductor device, a power source apparatus, and a high-frequency amplifier.

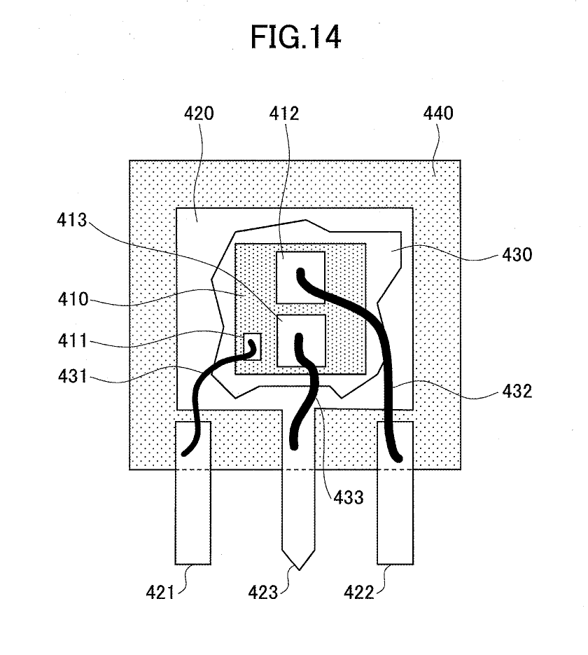

A semiconductor device according to the embodiment includes a semiconductor apparatus according to the first or second embodiment which is contained in a discrete package, and will be described based on FIG. 14. Note that FIG. 14 schematically illustrates the inside of the discretely packaged semiconductor apparatus in which positions of the electrodes and the like may be different from those in the first or second embodiment.

First, a substrate 110 is cut off by dicing or the like to form a semiconductor chip 410, which is a HEMT made of GaN semiconductor materials. This semiconductor chip 410 corresponds to the semiconductor chip 10 in the first embodiment, or the semiconductor chip 210 in the second embodiment. The semiconductor chip 410 is fixed on a lead frame 420 by a die attachment agent 430 such as solder.

Next, a gate electrode 411 is connected with a gate lead 421 by a bonding wire 431, a source electrode 412 is connected with a source lead 422 by a bonding wire 432, and a drain electrode 413 is connected with a drain lead 423 by a bonding wire 433. Note that the bonding wires 431, 432, and 433 are formed of a metal material such as Al. Also, the gate electrode 411 is a gate electrode pad according to the embodiment, which is connected with the gate electrode 21 of the semiconductor apparatus according to the first or second embodiment. Also, the source electrode 412 is a source electrode pad, which is connected with the source electrode 22 of the semiconductor apparatus according to the first or second embodiment. Also, the drain electrode 413 is a drain electrode pad, which is connected with the drain electrode 23 of the semiconductor apparatus according to the first or second embodiment.

Next, resin sealing is performed by a transfer molding method using a mold resin 440. Thus, the HEMT made of GaN semiconductor materials can be manufactured as the discretely packaged semiconductor apparatus.

Next, a power supply apparatus and a high frequency amplifier will be described according to the embodiment. The power source apparatus and the high-frequency amplifier according to the embodiment use the semiconductor apparatuses in the first or second embodiment.

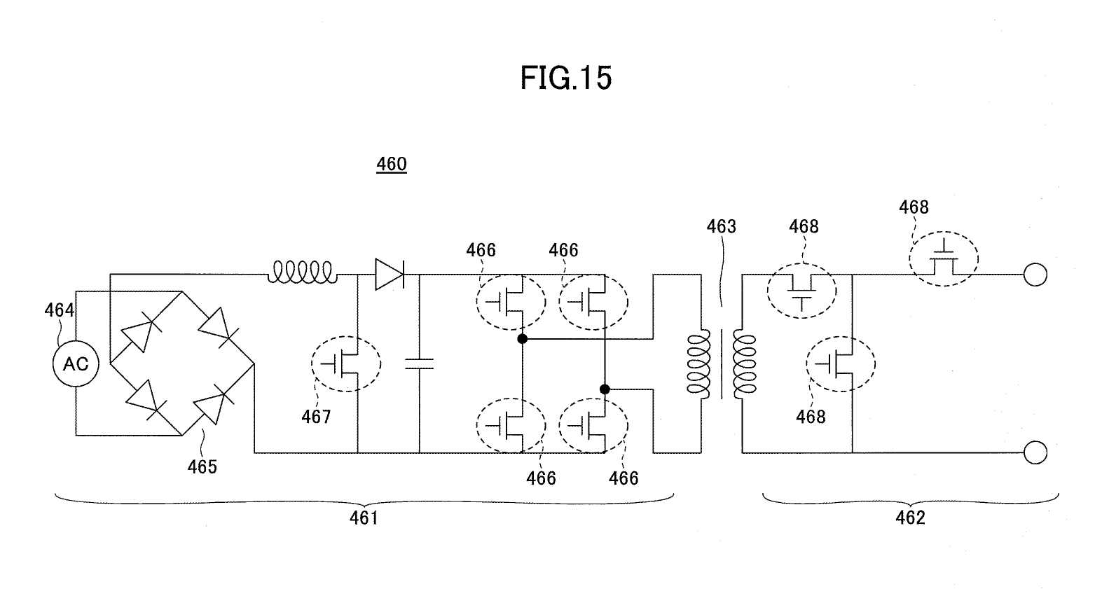

First, based on FIG. 15, the power source apparatus will be described according to the embodiment. The power source apparatus 460 according to the embodiment includes a high-voltage primary circuit 461, a low-voltage secondary circuit 462, and a transformer 463 disposed between the primary circuit 461 and the secondary circuit 462. The primary circuit 461 includes an AC power supply 464, a so-called “bridge rectifier circuit” 465, multiple (four in the example in FIG. 15) switching elements 466, and a switching element 467. The secondary circuit 462 includes multiple (three in the example in FIG. 15) switching elements 468. In the example in FIG. 15, semiconductor apparatuses according to the first or second embodiment are used as the switching elements 466 and 467 in the primary circuit 461. Note that it is preferable that the switching elements 466 and 467 in the primary circuit 461 are normally-off semiconductor apparatuses. Also, the switching elements 468 used in the secondary circuit 462 use usual MISFETs (metal insulator semiconductor field effect transistors) formed of silicon.

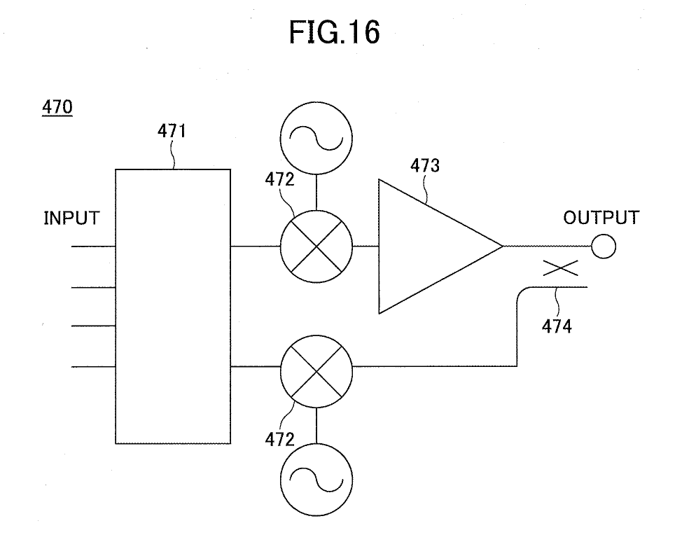

Next, based on FIG. 16, the high-frequency amplifier will be described according to the embodiment. The high frequency amplifier 470 according to the embodiment may be used for, for example, a power amplifier in a base station of cellular phones. This high-frequency amplifier 470 includes a digital predistortion circuit 471, mixers 472, a power amplifier 473, and a directional coupler 474. The digital predistortion circuit 471 compensates for non-linear distortion of an input signal. One of the mixers 472 mixes the input signal having non-linear distortion compensated, with an alternating current signal. The power amplifier 473 amplifies the input signal having been mixed with the alternating current signal. In the example illustrated in FIG. 16, the power amplifier 473 includes a semiconductor apparatus according to the first or second embodiment. The directional coupler 474 monitors the input signal and an output signal. In the circuit illustrated in FIG. 16, by turning on/off a switch, for example, it is possible to mix the output signal with an alternating current signal by using the other mixer 472, and to transmit the mixed signal to the digital predistortion circuit 471.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor apparatus comprising:
a semiconductor chip including
a first semiconductor layer formed over a substrate,
a second semiconductor layer formed over the first semiconductor layer, and
a gate electrode, a source electrode, and a drain electrode formed over the second semiconductor layer,
wherein the gate electrode is formed in a comb shape having a plurality of tooth parts,
wherein an interval between the tooth parts becomes narrower from a center part toward a peripheral part of the semiconductor chip,
wherein the source electrode is formed on one of two sides of each of the tooth parts in the gate electrode, and the drain electrode is formed on another of the two sides,
wherein the source electrodes and the drain electrodes formed between the tooth parts in the gate electrode have respective areas that are substantially the same in a plan view.

2. The semiconductor apparatus as claimed in claim 1, wherein the area of each of the source electrodes and the drain electrodes formed between the tooth parts, relative to an average of the areas of the source electrodes and the drain electrodes, is greater than or equal to 0.7 and less than or equal to 1.6.

3. The semiconductor apparatus as claimed in claim 1, wherein the area of each of the source electrodes and the drain electrodes formed between the tooth parts, relative to an average of the areas of the source electrodes and the drain electrodes, is greater than or equal to 0.85 and less than or equal to 1.25.

4. The semiconductor apparatus as claimed in claim 1, wherein some or all of the source electrodes and the drain electrodes are bi-partitioned, respectively.

5. The semiconductor apparatus as claimed in claim 4, wherein bi-partitioned parts of the source electrode are electrically connected with each other, and bi-partitioned parts of the drain electrode are electrically connected with each other.

6. The semiconductor apparatus as claimed in claim 4, wherein a high-heat-conduction part made of an insulator material is formed between the bi-partitioned parts of the source electrode, and between the bi-partitioned parts of the drain electrode.

7. The semiconductor apparatus as claimed in claim 6, wherein a passivation film is formed over the gate electrode, the source electrodes, and the drain electrodes,
wherein the high-heat-conduction part is also formed on the passivation film.

8. The semiconductor apparatus as claimed in claim 4, wherein an electrode width of the bi-partitioned parts of the source electrode and an electrode width of the bi-partitioned parts of the drain electrode are greater than or equal to 0.6 μm.

9. The semiconductor apparatus as claimed in claim 1, wherein a gate width of each of the tooth parts in the gate electrode is uniform,
wherein an interval between one of the tooth parts in the gate electrode and the source electrode closest to the one of the tooth parts is uniform,
wherein an interval between one of the tooth parts in the gate electrode and the drain electrode closest to the one of the tooth parts is uniform.

10. The manufacturing method as claimed in claim 1, wherein each of the first semiconductor layer and the second semiconductor layer is formed of a nitride semiconductor.

11. The semiconductor apparatus as claimed in claim 1, wherein the first semiconductor layer is formed of a material including GaN, and the second semiconductor layer is formed of a material including one of AlGaN, InAlN, and InAlGaN.

12. A power source apparatus comprising:
the semiconductor apparatus as claimed in claim 1.

13. An amplifier comprising:
the semiconductor apparatus as claimed in claim 1.
